(19) United States
(12) Patent Application Publication
(10) Pub. No.: US 2016/0079350 A1
(43) Pub. Date: Mar. 17, 2016

(54) SEMICONDUCTOR DEVICE AND MANUFACTURING METHOD THEREOF

(71) Applicant: KABUSHIKI KAISHA TOSHIBA, Tokyo (JP)

(72) Inventors: Hiroshi OHTA, Kanazawa Ishikawa (JP); Masaru IZUMISAWA, Kanazawa Ishikawa (JP); Syotaro ONO, Kanazawa Ishikawa (JP); Hiroaki YAMASHITA, Hakusan Ishikawa (JP); Takashi OKUHATA, Komatsu Ishikawa (US)

(21) Appl. No.: 14/624,312

(22) Filed: Feb. 17, 2015

(30) Foreign Application Priority Data
Sep. 16, 2014 (JP) 2014-187858

(51) Int. Cl. H01L 29/06; H01L 29/78; H01L 21/308; H01L 21/324; H01L 21/225; H01L 29/423; H01L 29/739

(52) U.S. Cl. CPC H01L 29/0634; H01L 29/4236; H01L 29/7811; H01L 29/7813; H01L 29/7397; H01L 29/0684; H01L 21/324; H01L 21/2251; H01L 21/308

(57) ABSTRACT

A semiconductor device includes a first semiconductor region of a first conductivity type, an element region, a terminal region, and a second electrode. The element region includes a second semiconductor region of a second conductivity type, a third semiconductor region of the second conductivity type, a fourth semiconductor region of the first conductivity type, a gate electrode, and a first electrode. The terminal region includes a fifth semiconductor region of the second conductivity type, and a sixth semiconductor region of the second conductivity type. The terminal region surrounds the element region. The fifth semiconductor region is provided within the first semiconductor region. A plurality of the fifth semiconductor regions are provided along a second direction. The sixth semiconductor region is provided between the first semiconductor region and the fifth semiconductor region. A dopant of the sixth semiconductor region is higher than a dopant concentration of the fifth semiconductor region.

### CROSS-REFERENCE TO RELATED APPLICATION

This application is based upon and claims the benefit of priority from Japanese Patent Application No. 2014-187858, filed Sep. 16, 2014, the entire contents of which are incorporated herein by reference.

### FIELD

Embodiments described herein relate generally to a semiconductor device and a method of manufacturing the same.

### BACKGROUND

In order to control power, a semiconductor device, such as a Metal Oxide Semiconductor Field Effect Transistor (MOSFET) and an Insulated Gate Bipolar Transistor (IGBT), is used. In these semiconductor devices, a super junction structure is formed in order to reduce ON resistance while maintaining a desired breakdown voltage.

### DESCRIPTION OF THE DRAWINGS

FIG. 1 is a top plan view illustrating an example of a semiconductor device according to a first embodiment.

FIGS. 2A and 2B are cross-sectional views of FIG. 1 at section A-A (FIG. 2A) and section B-B (FIG. 2B) illustrating an example of the semiconductor device according to the first embodiment.

FIG. 3 is a top plan view illustrating an example of a super junction structure of the semiconductor device according to the first embodiment.

FIG. 4 is a top plan view illustrating another example of the super junction structure of the semiconductor device according to the first embodiment.

FIGS. 5A and 5B are a cross-sectional view illustrating an example of a semiconductor device according to a second embodiment.

FIGS. 6A and 6B are a cross-sectional view illustrating an example of a semiconductor device according to a third embodiment.

FIGS. 7A, 7B, and 7C are a cross-sectional view illustrating an example of a manufacturing process of the semiconductor device according to the first embodiment.

FIGS. 8A and 8B are a cross-sectional view illustrating an example of a manufacturing process of the semiconductor device according to the first embodiment.

### DETAILED DESCRIPTION

There is to provide a semiconductor device and a method of manufacturing the same capable of improving avalanche resistance while suppressing an increase in an ON resistance.

In general, according to one embodiment, a semiconductor device includes a first semiconductor region of a first conductivity type, an element region, a terminal region, and a second electrode.

The element region includes a second semiconductor region of a second conductivity type, a third semiconductor region of the second conductivity type, a fourth semiconductor region of the first conductivity type, a gate electrode, and a first electrode.

The second semiconductor region is provided within the first semiconductor region. The second semiconductor region extends inwardly of the first semiconductor region in a first direction. A plurality of the second semiconductor regions are provided along a second direction orthogonal to the first direction.

The third semiconductor region is provided on the second semiconductor region.

The fourth semiconductor region is selectively provided on the third semiconductor region.

The gate electrode faces the first semiconductor region, the third semiconductor region, and the fourth semiconductor region through a first insulating film.

The first electrode is electrically connected to the fourth semiconductor region.

The terminal region includes a fifth semiconductor region of the second conductivity type and a sixth semiconductor region of the second conductivity type. The terminal region surrounds the element region.

The fifth semiconductor region is provided inwardly of the first semiconductor region in the first direction. A plurality of the fifth semiconductor regions are arranged in the second direction.

The sixth semiconductor region is provided between the first semiconductor region and the fifth semiconductor region. A dopant concentration of the second conductivity type of the sixth semiconductor region is higher than a dopant concentration of the fifth semiconductor region.

The second electrode is electrically connected to the first semiconductor region.

Embodiments of this disclosure will be hereinafter described with reference to the drawings.

Here, the drawings are schematic or conceptual and a relation between thickness and width of each component and a ratio of the size of each component are not always equal to those of an actual device. When the same features are shown in the drawing figures, the size and ratio thereof may be expressed differently in different drawings.

Where, the same reference numerals and symbols are used in different drawings for the same elements, a second description thereof will be omitted in this disclosure unless needed to understand the interrelationship of the elements.

Arrows X, Y, and Z in each drawing indicate three directions orthogonal to each other; for example, a direction indicated by the arrow X (X direction) and a direction indicted by the arrow Y (Y direction) show a direction in parallel to the main surface of a semiconductor substrate and a direction indicated by the arrow Z (Z direction) shows a direction perpendicular to the main surface of the semiconductor substrate.

In the drawings, the expressions of n⁺, n and p⁺, p, p⁻ indicate a relative degree of the dopant concentration in conductivity type in each of respective semiconductor regions. Specifically, n⁺ material has a relatively higher dopant concentration of n type than an n doped material. Further, the p⁺ material has a relatively higher dopant concentration of p type than the a p doped material, and the p⁻ material has a relatively lower dopant concentration of p type dopants than the p type material.

The respective embodiments described herein may be realized with the p type and the n type dopants switched in each semiconductor region.

### First Embodiment

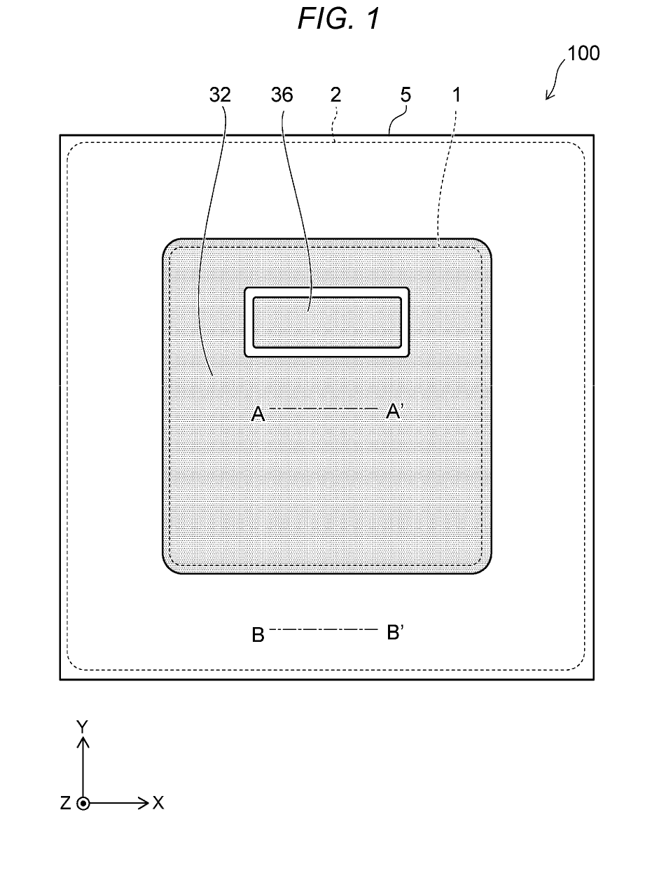

FIG. 1 is a top plan view illustrating a semiconductor device according to a first embodiment.

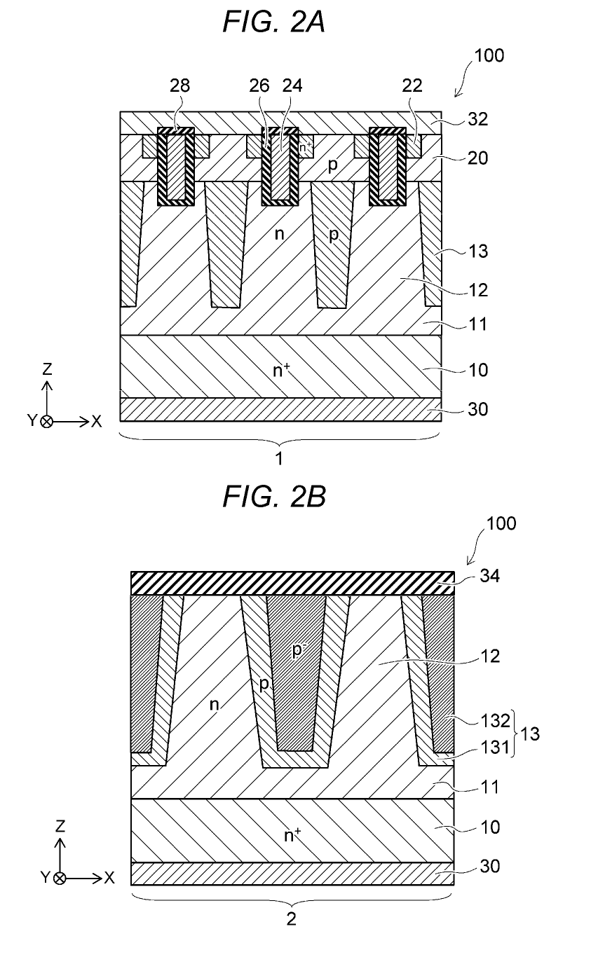

FIGS. 2A and 2B are a cross-sectional view illustrating the semiconductor device according to the first embodiment.

FIG. 2A is a cross-sectional view taken along the line A-A′ in FIG. 1.

FIG. 2B is a cross-sectional view taken along the line B-B′ in FIG. 1.

A semiconductor device 100 includes a first semiconductor region of a first conductivity type, a plurality of second semiconductor regions of a first conductivity type, a plurality of third semiconductor regions of a second conductivity type, a fourth semiconductor region of a second conductivity type, a fifth semiconductor region of a first conductivity type, a sixth semiconductor region of a first conductivity type, a gate electrode, a drain electrode, and a source electrode.

The semiconductor device 100 is, for example, MOSFET.

As illustrated in FIG. 1, a semiconductor substrate 5 (hereinafter, referred to as a substrate 5) includes an element region 1 and a joint terminal region 2 (hereinafter, referred to as a terminal region 2) provided around the outer side of the element region 1 such that the element region 1 is surrounded by the terminal region 2. A source electrode 32 is provided in the element region 1. A plurality of MOSFETs are provided below the source electrode 32.

An opening is provided in the source electrode 32. A gate pad 36 is provided in the opening and spaced from the source electrode 32. This gate pad 36 is electrically connected to the gate electrodes 24 of the MOSFETs provided under the source electrode 32.

As illustrated in FIGS. 2A and 2B, a drain region 10 is provided in the element region 1 and the terminal region 2. The drain region 10 is an n type semiconductor region. The drain region 10 is electrically connected to the drain electrode 30.

The n type semiconductor region 11 is provided on the drain region 10. The n type dopant concentration of the n type semiconductor region 11 is lower than that of the drain region 10.

The n type semiconductor region 11 includes a plurality of n type pillars 12 extending in the Y direction, and in a direction away from the drain electrode 30, and regularly spaced apart in the X direction to form a comb-like structure, which extends from an underlying continuous portion of the n-type semiconductor region 11 overlying the drain electrode 10 with interdigited n-type pillars 12 and p-type pillars 13 interdigited in the X direction and each extending generally linearly in the Y direction.

A plurality of p type doped semiconductor pillars 13 extend in the Y direction inwardly of the spaces between adjacent n-type pillars 13.

The n type pillars 12 and the p type pillars 13 are alternately provided across the X direction of the device as shown in FIGS. 2A and 2B. In short, except at the terminal region to the right and left of FIGS. 2A and 2B, a p type pillars 13 is provided between adjacent n type pillars 12 and n type pillars 12 are provided between adjacent p type pillars 13.

For example, the n type semiconductor region 11 is a region included in one semiconductor layer and the n type pillars 12 extend from this n type semiconductor region 11. In this case, the n type semiconductor region 11, the n type pillars 12, and the p type pillars 13 are formed, for example, by forming an n type semiconductor layer on drain electrode 30, forming trenches extending inwardly of n type semiconductor region 11 in the direction of the drain electrode, and depositing a p type semiconductor into the trenches. Here, the p type semiconductor layer embedded into the trench forms the p type pillar 13 extending inwardly of the n type semiconductor region 11.

Alternatively, the n type semiconductor region 11 may be formed by a plurality of semiconductor layers and the n type pillar 12 may be a part of the n type semiconductor region 11. In this case, the n type semiconductor region 11, the n type pillars 12, and the p type pillars 13 are formed, for example, by first epitaxially growing the n type semiconductor layer on the surface of an n type semiconductor substrate, forming trenches on the epitaxial n type semiconductor layer, and depositing the p type semiconductor into the trenches. Here, the p type semiconductor layer embedded into the trench forms the p type pillar 13 and the epitaxial n type semiconductor substrate and n type semiconductor layer form the n type semiconductor region 11. The space between the p type pillars 13 into which the semiconductor region 11 extends forms the n type pillar 12.

In the example shown in FIGS. 2A and 2B, a distance between the adjacent n type pillars 12 in the terminal region 2 in the X direction is larger than a distance between the adjacent n type pillars 12 in the element region 1 in the X direction. A distance between the adjacent p type pillars 13 in the terminal region 2 in the X direction is equal to a distance between the adjacent p type semiconductor regions 13 in the element region 1 in the X direction.

The width of the n type pillar 12 in the terminal region 2 in the X direction is equal to the width of the n type pillar 12 in the element region 1. The sum of the widths of the p type semiconductor region 131 and the width of the p⁻ type semiconductor region 132 in the X direction in the terminal region 2 is larger than the width of each of the p type pillars 13 in the element region 1 in the X direction.

As illustrated in FIG. 2B, in the terminal region 2, the p type pillar 13 includes a p type semiconductor region 131 formed over a p type semiconductor region 132. The p type semiconductor region 131 is provided in the outer periphery of the p⁻ type semiconductor region 132. In other words, the p type semiconductor region 131 is provided between the p⁻ type semiconductor region 132 and the n type pillar 12 and between the p type semiconductor region 132 and the n type semiconductor region 11. The p type semiconductor region 131 may be provided only between the p⁻ type semiconductor region 132 and the n type pillar 12.

In the element region 1, a base region 20 is provided on the p type pillars 13 and portions of the n type pillars 12. The base region 20 is a p type semiconductor region.

A source region 22 is selectively provided on the base region 20. The source region 22 is an n type semiconductor region. The n type dopant concentration of the source region 22 is higher than that of the n type semiconductor region 11, and higher than that of the n type pillar 12.

Trenches extend through adjacent source regions 22 and base regions 20 and inwardly of an n-type pillars 12 terminating therein, and include a gate insulating film 26 formed along the base and walls thereof and a gate electrode 24 formed over the gate insulating film 26 to fill the trench.

A source electrode 32 is provided over the base regions 20, the source regions 22 and the gate electrodes 24. The gate electrodes 24 and the source electrode are electrically isolated from one another by an insulating layer film 28 formed over the upper terminus of the gate electrode 24. The source regions 22 are electrically connected to the source electrode 32.

By applying a voltage equal to or greater than a threshold voltage to the gate electrode 24, a channel (inversion layer) is formed in the vicinity of the gate insulating film 26 in the p base region 20 and the MOSFET is switched to an ON state.

When the MOSFET is in an OFF state and a positive potential is applied to the drain electrode 30 with respect to the potential of the source electrode 32, a depletion layer expands from the pn joint surface of the n type pillar 12 and the p type pillar 13 and into the n type pillar 12 and the p type pillar 13. The n type pillar 12 and the p type pillar 13 are depleted in a perpendicular direction with respect to the joint surface of the n type pillar 12 and the p type pillar 13, to suppress the electric field concentration in a direction parallel to the joint surface of the n type pillar 12 and the p type pillar 13; therefore, a high breakdown voltage may be obtained.

in the terminal region 2, an insulating layer 34 is provided on the n type pillars 12 and the p type pillars 13. A field plate electrode and a protective layer may be provided on the insulating layer 34.

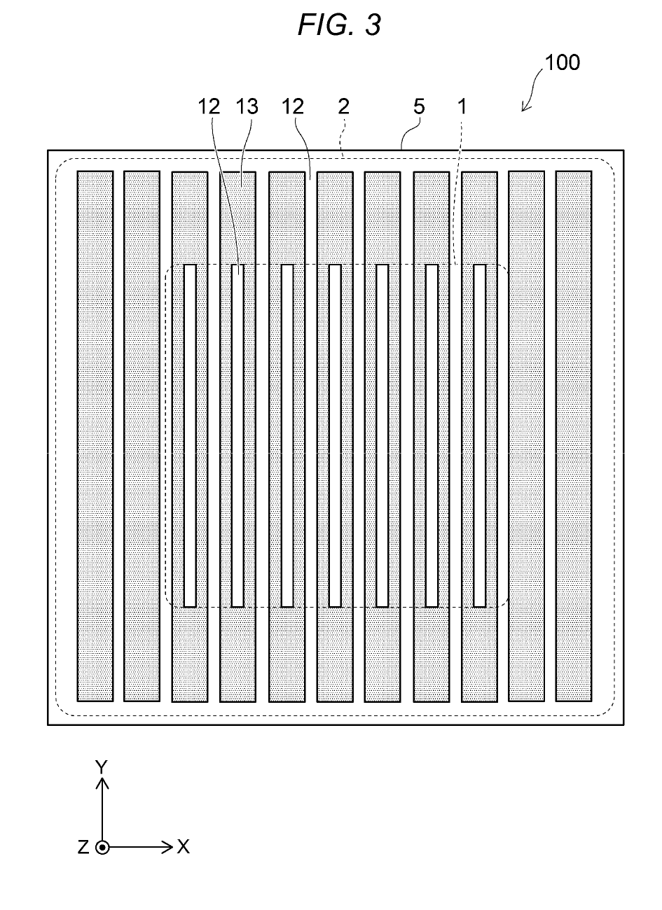

An example of the structure of the n type pillar 12 and the p type pillar 13 in the element region 1 and in the terminal region 2 will be described with reference to FIG. 3.

FIG. 3 is a top plan view illustrating a semiconductor device 100 according to the first embodiment. In FIG. 3, the structure of the device other than the n type pillar 12 and the p type pillar 13 is omitted.

As illustrated in FIG. 3, of the n type pillars 12 provided in the element region 1, some n type pillars 12 extend to the vicinity of the outer periphery of the terminal region 2 and the other n type pillars 12 are provided only in the element region 1.

Therefore, in the X direction, a distance between the adjacent n type pillars 12 in the terminal region 2 is larger than a distance between the adjacent n type pillars 12 in the element region 1. On the other hand, in the X direction, a distance between the adjacent p type pillars 13 in the terminal region 2 is equal to a distance between the adjacent p type pillars 13 in the element region 1.

Here, function and effect of the semiconductor device 100 according to the embodiment will be described.

In the terminal region, the p type semiconductor region 131 having a higher p type dopant concentration than that of the p⁻ type semiconductor region 132 forming the p type pillar 13 in the terminal region 2 between the p⁻ type semiconductor region 132 and the n type pillar 12, makes it possible to suppress an increase in the ON resistance of the semiconductor device and to improve the avalanche resistance.

The reasons are as follows.

When a voltage applied to the gate electrode 24 is removed to turn off the MOSFET, a voltage is generated between the drain and the source of FET according to the inductance component in an electric circuit including the semiconductor device 100. When this generated voltage exceeds a voltage capable of generating an avalanche breakdown, electrons and holes are generated in each semiconductor region of the semiconductor device 100 according to the avalanche breakdown. Here, the electrons flow to the drain electrode 30 and the holes flow to the source electrode 32.

The drain region 10 extends under the n type semiconductor region 11 and the contact area of the drain region 10, and the drain electrode 30 is large enough to allow the generated electrons to efficiently discharge through the drain electrode 30. On the other hand, the generated holes are discharged to the source electrode 32 through the p type pillar 13 and the base region 20. Since the source regions 22 and the gate electrodes 24 are provided between the base region 20 and the source electrode 32, the area of the base region 20 through which the holes can pass is to the source electrode 32 is smaller than that of the drain region 10 and the drain electrode 30. Therefore, discharging the holes to the source electrode is more difficult than discharging the electrons to the drain electrode 30rge.

As the time needed to discharge the holes from the semiconductor region gets longer because of the relative restriction on the movement thereof through a smaller cross sectional area than that available for electrons to flow to the drain electrode 30, the voltage in the semiconductor region rises. For example, when the voltage between the base region 20 and the n type pillar 12 gets to the ON voltage and a parasitic transistor is formed by the source region 22, the base region 20, and the n type pillar 12, an excessive current flows in the semiconductor region and will destroy the FET. It is, therefore, desirable that the generated holes are efficiently discharged.

Generally, the holes generated in the n type semiconductor region 11 and the n type pillar 12 pass the outer periphery of the p type pillar 13 and flow to the base region 20. Specifically, the generated holes pass the vicinity of the boundary of the n type pillar 12 and the p type pillar 13, of the p type pillar 13, and flow to the base region 20.

In the embodiment, in the terminal region 2 the p type semiconductor region 131 having a high dopant concentration of p type is provided between the p⁻ type semiconductor region 132 and the n type pillar 12. Therefore, an electric resistance to the holes is smaller in the outer periphery (in region 131) of the p type pillar 13 passing the holes to the base region 20. Accordingly, the holes are efficiently discharged by passing through the p type semiconductor region 131, thereby suppressing an increase in the voltage of the semiconductor region and improving the avalanche resistance.

Here, the p type semiconductor region 131 is preferably provided only in the terminal region 2.

In order to reduce the ON resistance in the semiconductor device, it is desirable that the number of the n type pillars 12 that are current channels is greater in the element region 1 than in the terminal region 2. If the p⁻ type semiconductor region 132 and p type semiconductor layer 132 having a lower dopant concentration of p type is provided in the element region 1, the intervals of the n type pillars 12 will increase according to an increase in the width of the p type pillar 13 in the X direction. As a result, the number of the n type pillars 12 will be reduced and the ON resistance will increase.

Accordingly, by providing the p type semiconductor region 132 only in the terminal region 2 and providing the p type semiconductor region 131 in the terminal region 2 between the p⁻ type semiconductor region 132 and the n type pillar 12, it is possible to improve the avalanche resistance while suppressing an increase in the ON resistance of the semiconductor device.

### Modified Example

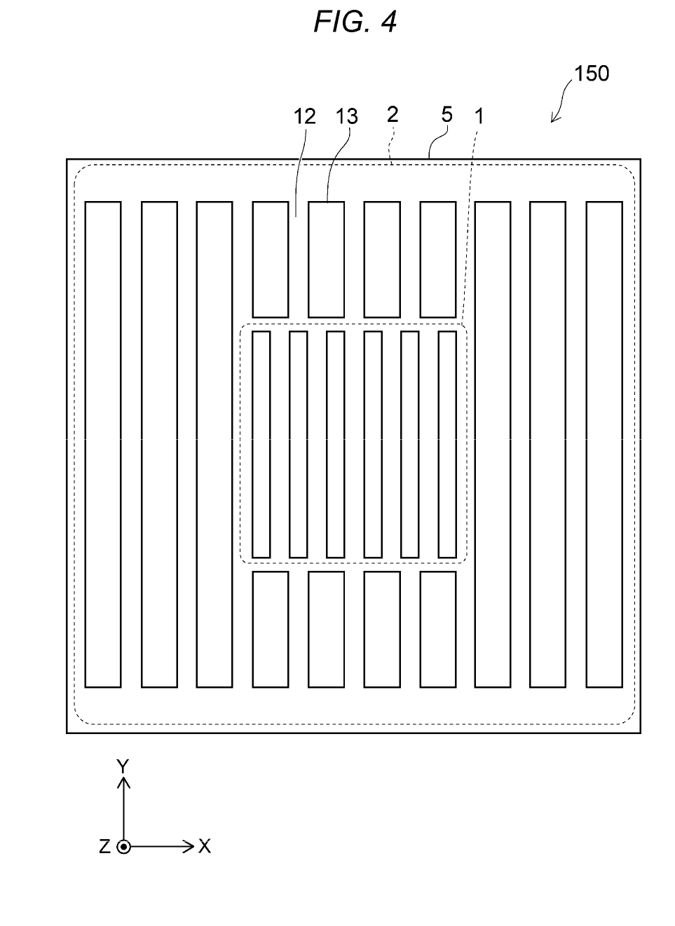

A modified example of the above-mentioned embodiment will be described with reference to FIG. 4.

FIG. 4 is a top plan view of a semiconductor device 150 according to the modified example of the first embodiment. In FIG. 4, device structures other than the n type pillar 12 and the p type pillar 13 is omitted.

In the example illustrated in FIG. 3, some n type pillars 12 are continuously formed in the element region 1 and in the terminal region 2. Additionally, in this modified example, as illustrated in FIG. 4, the p type pillars 13 are discontinuous in the vicinity of the boundaries of the element region 1 and the terminal region 2 in the Y direction.

According to the modified example, a distance (spacing) in the X direction between adjacent p type pillars 13 and n-type pillars 12 may be designed separately in the element region 1 and in the terminal region 2.

Also in the modified example, similarly to the semiconductor device 100, by providing the p type semiconductor region 131 having a higher dopant concentration of a second conductivity type than that of the p⁻ type semiconductor region 132 in the p type pillar 13 between the p⁻ type semiconductor region 132 and the n type pillar 12 in the terminal region 2, it is possible to improve the avalanche resistance while suppressing an increase in the ON resistance of the semiconductor device.

### Second Embodiment

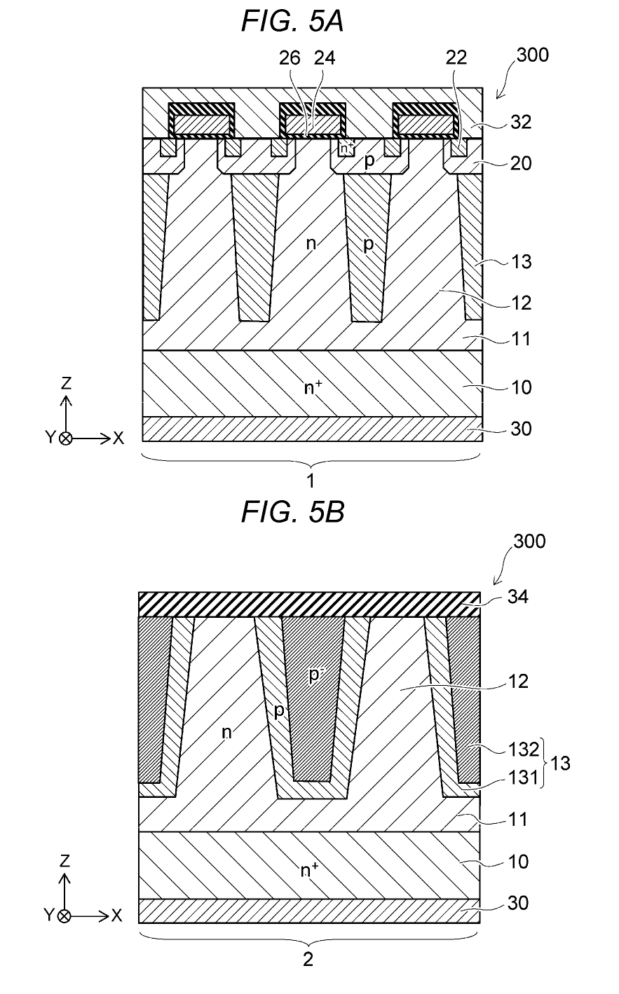

FIGS. 5A and 5B are a cross-sectional view illustrating a semiconductor device according to a second embodiment.

A semiconductor device 100 according to the first embodiment is a so-called trench type MOSFET with the gate electrodes 24 extending over the n-type semiconductor layer 12 between adjacent the base regions 20 having source regions 22 embedded therein.

On the other hand, a semiconductor device 300 according to the embodiment is a so-called planar type MOSFET with a gate electrode provided on the substrate surface.

The other structures of the device, for example, the structure of the n type pillars 12 and the p type pillars 13 and there relative locations with respect to one another is the same as the first embodiment.

According to the embodiment, similarly to the first embodiment, it is possible to improve the avalanche resistance while suppressing an increase in the ON resistance of the semiconductor device.

### Third Embodiment

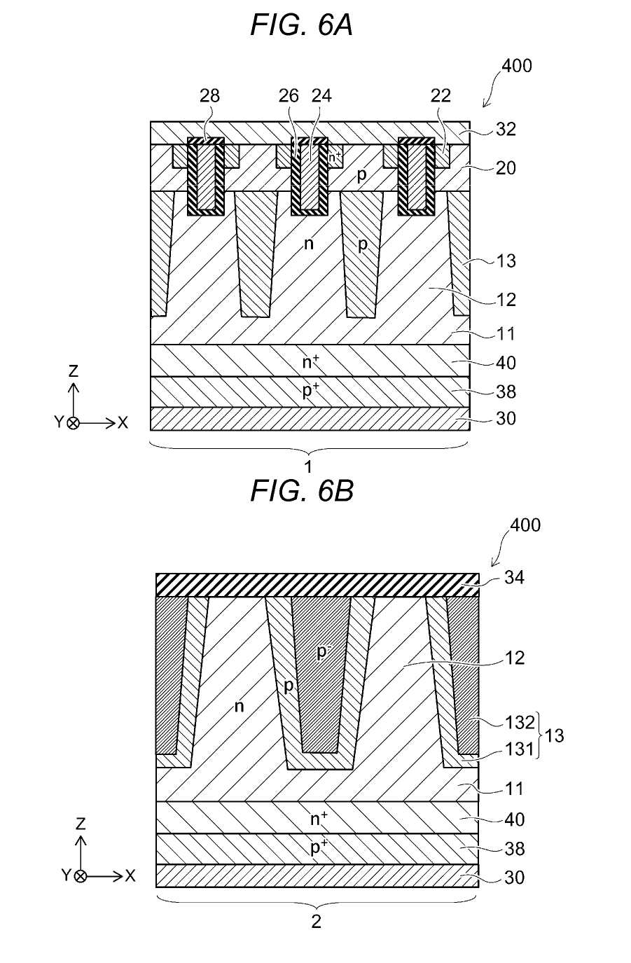

FIGS. 6A and 6B are a cross-sectional view of a semiconductor device according to a third embodiment.

In FIGS. 6A and 6B, the same reference numerals and symbols as used in FIGS. 2A and 2B are attached to the components that may be formed in the same structure as the first embodiment and the detailed description thereof is properly omitted.

A semiconductor device 400 according to the third embodiment is, for example, IGBT.

The semiconductor device 400 includes a buffer region 40 and a collector region 38, instead of the drain region 10 in the semiconductor device 100. Further, the semiconductor device 400 includes an emitter region 22, a collector electrode 30, and an emitter electrode 32.

The buffer region 40 is an n type semiconductor region. The n type dopant concentration of the buffer region 40 is higher than that of the n type semiconductor region 11.

The collector region 38 is a p type semiconductor region. The p type dopant concentration of the collector region 38 is higher than the n type dopant concentration of the n type semiconductor region 11. The p type dopant concentration of the collector region 38 is equal to, for example, the n type dopant concentration of the buffer region 40.

The buffer region 40 is provided on the collector region 38. The buffer region 40 and the collector region 38 are provided in the element region 1 and in the terminal region 2.

The collector region 38 is electrically connected to the collector electrode 30. Further, the emitter region 22 is electrically connected to the emitter electrode 32.

The n type semiconductor region 11 is provided on the buffer region 40.

The other structures, for example, the structure of the n type pillar 12 and the p type pillar 13 and there relative position is the same as that illustrating the first embodiment.

According to the embodiment, similarly to the first embodiment, it is possible to improve the avalanche resistance while suppressing an increase in the ON resistance of the semiconductor device.

(Manufacturing Method)

A method of manufacturing the semiconductor device 100 according to the first embodiment will be described.

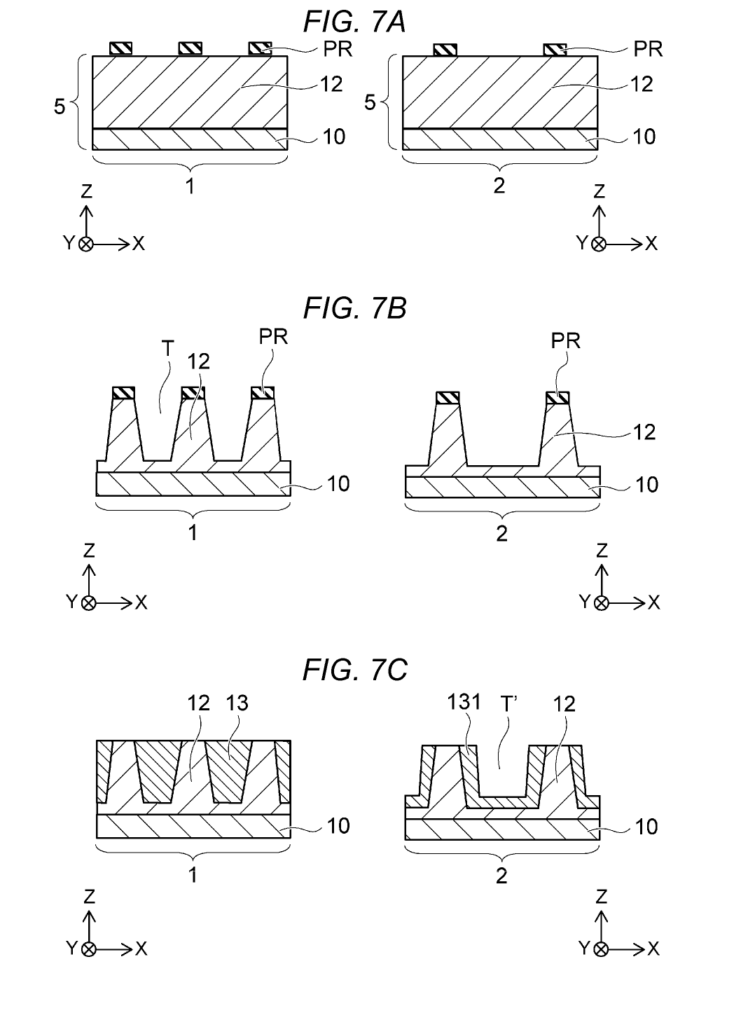

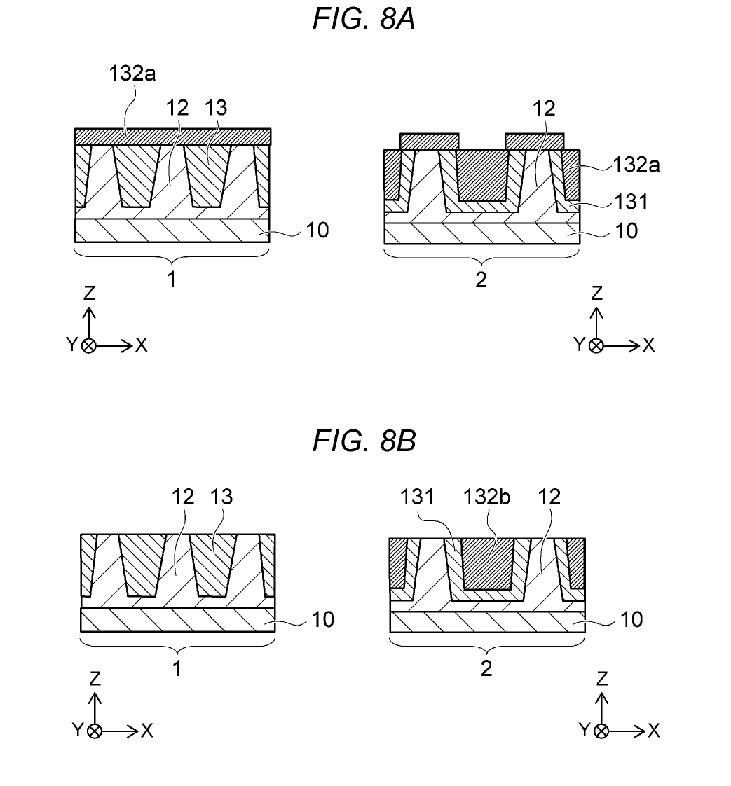

FIGS. 7A, 7B, and 7C and FIGS. 8A and 8B are cross-sectional views illustrating a manufacturing process of the semiconductor device 100 according to the first embodiment. In each figure, the left view shows the state of the element region 1 and the right view shows the state of the terminal region 2.

As illustrated in FIG. 7A, a photoresist PR is formed on the n type substrate 5 where the drain region 10 is formed. The photoresist PR is patterned according to the shape of the trenches to be formed into the n-type semiconductor region 12.

Next, as illustrated in FIG. 7B, the n-type semiconductor region 12 is etched using photoresist PR to define the limits of the trenches T extending therein. The n type semiconductor region between the trenches T corresponds to the n type pillar 12. The width of the trench T formed in the element region 1 is smaller than the width of the trench T formed in the terminal region 2, in the X direction. Further, the width of the n type pillar 12 formed in the element region 1 is equal to the width of the n type pillar 12 formed in the terminal region 2, in the X direction.

When forming the trenches T, the photoresist PR may be used to form a patterned hard mask and the hard mask may be used to form the trenches T in the substrate 5.

As illustrated in FIG. 7C, a p type semiconductor film is formed on the substrate 5 and portions of the semiconductor film existing on the surface of the substrate 5 are removed. The semiconductor film is deposited, for example, by the epitaxial growth method. Here, in the element region 1, a p type semiconductor layer is formed embedded in the trench T. On the other hand, in the terminal region 2, since the width of the trench T in the X direction is large, the trench T is not fully filled but the p type semiconductor layer is formed along the inner wall of the trench T. In the terminal region 2, a trench T′ is formed to have a width wider than a width of the trench T in the X direction.

In the element region 1, the semiconductor layer embedded in the trench T corresponds to the p type pillar 13. In the terminal region 2, the semiconductor layer formed along the inner wall of the trench T corresponds to the p type semiconductor region 131.

Next, as illustrated in FIG. 8A, a non-doped Si film 132a is deposited on the substrate 5. In the element region 1, since the p type semiconductor layer has been already embedded in the trench T, the Si film 132a is deposited on the surface of the substrate 5. On the other hand, in the terminal region 2, the Si film 132a is deposited within the trench T′ and over the upper surface of semiconductor film 131 and pillar 12. Here, the trench T′ is filled with the Si film 132a.

As illustrated in FIG. 8B, an extra Si film existing on the surface of the substrate 5 is removed. According to this process, a non-doped Si layer 132b is formed within the trench T′.

Then, by heating the semiconductor substrate 5, the p type dopant is diffused from the p type semiconductor region 131 to the Si layer 132b, to form a p⁻ type semiconductor region 132.

Then, the semiconductor device 100 is obtained by forming the other semiconductor regions, electrodes, and insulating layers.

Function and effect by the manufacturing method will be described.

As mentioned above, a p type semiconductor layer is formed in a trench formed in the terminal region 2 and a non-dope semiconductor layer is formed to fill the trench in the terminal region 2, thereby making it possible to suppress a reduction of the avalanche resistance in the semiconductor device 100.

The reasons are as follows.

In a semiconductor device having a super junction structure, when Qn is equal to Qp, the highest avalanche resistance may be obtained. The larger a difference between Qn and Qp becomes, the more the avalanche resistance in a semiconductor device is reduced.

When a trench is formed in an n type semiconductor substrate and filled with a p type semiconductor material, if there is a variation in the width and the depth of the trench, a balance between Qn and Qp will be lost, and can be remarkably different. This is because, for example, when the width of the trench is larger than the designed width, Qn is reduced according as the n type pillar becomes thinner and, further, Qp is increased as the width of the p type semiconductor layer embedded in the trench becomes larger.

In the MOSFET using the super junction structure, when Qn is equal to Qp, the highest breakdown voltage may be obtained and when a difference occurs between Qn and Qp, a breakdown voltage is reduced in accordance with the difference between Qn and Qp. Especially, in the terminal region 2, when a difference between Qn and Qp occurs, a reduction of the breakdown voltage is larger than that in the element region 1. Therefore, when it is in an avalanche state in a case that a difference between Qn and Qp occurs, holes are generated in the terminal region 2 prior to forming in the element region 1.

However, the terminal region 2 has a smaller contact area with the source electrode 32, as compared to the element region 1. Therefore, it is difficult to discharge the holes generated in the terminal region 2 from the source electrode 32 as compared to those generated in the element region 1. As a result, the avalanche resistance is reduced.

On the other hand, in the embodiment, after a constant amount of p type semiconductor material is deposited on the trench in the terminal region, a non-doped semiconductor material is deposited to fill the trench. Therefore, the width and the depth of the trench vary and even when Qn fluctuates, Qp of the deposited semiconductor material does not change due to the variation of the width and the depth of the trench.

Accordingly, as compared to the case of forming a super junction structure by embedding a p type semiconductor material in a trench in the terminal region, a difference between Qn and Qp caused by the manufacturing variation of the trench may be reduced. As a result, a reduction in the avalanche resistance caused by the difference between Qn and Qp may be suppressed.

Further, by forming trenches so that the width, in the X direction, of a trench in the terminal region is larger than the width of a trench in the element region, the p type pillar 13 in the element region 1 and the p type semiconductor region 131 in the terminal region 2 may be formed in fewer processes.

When, in the X direction, the width of the n type pillar 12 in the terminal region 2 is equal to the width of the n type pillar 12 in the element region 1 and in the X direction, the width of the trench in the terminal region is equal to the width of the trench in the element region, if the p type semiconductor material is deposited in the terminal region 2, similarly to the element region 1, the trench in the terminal region 2 will be filled with the p type semiconductor material. In order to avoid this and make small a difference between Qn and Qp in the terminal region 2, a film formation process has to be performed separately in the element region 1 and in the terminal region 2.

When the width in the X direction of the n type pillar 12 in the terminal region 2 is smaller than the width of the n type pillar 12 in the element region 1 and the width in the X direction of the trench in the terminal region is equal to the width of the trench in the element region, similarly, the film formation process has to be performed respectively in the element region 1 and in the terminal region 2 in order to make a difference between Qn and Qp in the terminal region 2 be small.

However, by forming trenches so that the width in the X direction of a trench in the terminal region 2 is larger than the width in the X direction of a trench in the element region 1, the p type semiconductor material may be deposited simultaneously in the element region 1 and in the terminal region 2, to form the p type pillar 13 in the element region 1 and the p type semiconductor region 131 in the terminal region 2.

A relative level of the dopant concentration in each semiconductor region, described in the above-mentioned respective embodiments, may be confirmed, for example, using a scanning capacitance microscopy (SCM).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor region of a first conductivity type;
an element region including:
a plurality of second semiconductor regions of a second conductivity type extending inwardly of the first semiconductor region in a first direction and arranged along a second direction orthogonal to the first direction,
a third semiconductor region of the second conductivity type provided on the second semiconductor region,
a fourth semiconductor region of the first conductivity type selectively provided on the third semiconductor region,
a gate electrode extending inwardly of the first semiconductor region, and through the third semiconductor region and the fourth semiconductor region;
a first insulating film disposed between the gate electrode and the first semiconductor region, third semiconductor region and the fourth semiconductor region; and
a first electrode electrically connected to the fourth semiconductor region;
a terminal region that surrounds the element region, including:
a plurality of fifth semiconductor regions of the second conductivity type extending inwardly of the first semiconductor region in the first direction and arranged along the second direction, and
a sixth semiconductor region of the second conductivity type disposed between the first semiconductor region and the fifth semiconductor region, having a dopant concentration of the second conductivity type higher than a dopant concentration of the second conductivity type of the fifth semiconductor region; and
a second electrode electrically connected to the first semiconductor region.

2. The device according to claim 1, wherein
a sum of widths in the second direction of the fifth semiconductor region and of the sixth semiconductor region on either side of fifth semiconductor is greater than a width in the second direction of the second semiconductor region.

3. The device according to claim 2, wherein
a distance in the second direction between adjacent sixth semiconductor regions disposed on different adjacent fifth semiconductor regions is equal to a distance in the second direction between the adjacent second semiconductor regions.

4. The device according to claim 2, wherein the third semiconductor region extends over at least a portion of the first semiconductor region.

5. The device according to claim 4, wherein the third semiconductor region extends over the portion of the first semiconductor region between the second semiconductor region and the gate insulating film.

6. The device according to claim 1, wherein the first electrode is electrically connected to the third semiconductor region.

7. The device according to claim 1, wherein the first electrode extends over the gate electrode.

8. The device according to claim 1, further comprising a second insulating film located between the first electrode and the gate electrode.

9. The device according to claim 1, further comprising a seventh semiconductor region of the first conductivity type disposed on the first semiconductor region side thereof opposed to side into which the second semiconductor regions extend.

10. The device according to claim 1, further comprising a second electrode electrically connected to the seventh semiconductor region.

11. The device according to claim 1, further comprising an eighth semiconductor region of the second conductivity type connected to the sixth semiconductor region, and
a second electrode electrically connected to the eighth semiconductor region.

12. A method of manufacturing a semiconductor device, comprising:
providing a semiconductor layer of a first conductivity type;
forming a plurality of trenches extending in a first direction into the semiconductor layer of the first conductivity type, such that a width of a trench formed in a first region of the semiconductor layer is smaller than a width of a trench in a second region of the semiconductor layer surrounding the first region;
depositing a semiconductor material of a second conductivity type and filling the trench formed in the first region and forming a first semiconductor layer on an inner wall of the trench formed in the second region; and
depositing a non-doped semiconductor material on the semiconductor substrate to form a second non-doped semiconductor layer in the trench over the semiconductor material of the second conductivity type formed in the trench in the second region.

13. The method of manufacturing a semiconductor device of claim 12, further comprising:
heating the non-doped semiconductor material and diffusing the dopants of the semiconductor material of the second conductivity type into the non-doped semiconductor material.

14. The method of claim 12, further wherein the trenches in the semiconductor layer of the first conductivity type are formed by:
providing a patterned etch mask having a first spacing in the first region of the semiconductor layer of the first conductivity type and a second spacing, larger than the first spacing, in the second region of the semiconductor layer of the first conductivity type; and,
etching trenches into the semiconductor layer of the first conductivity type in the first and second region using the patterned mask to form wider trenches in the second region of the semiconductor layer of the first conductivity type than the trenches formed in the first region of semiconductor layer of the first conductivity type.

15. The method of claim 12, further comprising epitaxially growing the second non-doped semiconductor layer over the semiconductor material of the second conductivity type formed in the trench in the second region.

16. A semiconductor device, comprising:
a first semiconductor layer of a first conductivity type extending into a first region and a second region;
a plurality of first pillars of the first semiconductor layer extending from a base region of the first semiconductor layer in a spaced parallel relationship;
a plurality of second pillars of a second semiconductor material of a second conductivity type interposed between the first pillars of the first semiconductor layer extending from a base region of the first semiconductor layer in the first and the second regions; and,
a third semiconductor material of the second conductivity type interposed between the first pillars and the second pillars.

17. The semiconductor device of claim 16, further comprising a gate electrode extending inwardly of the first pillars in the first region and spaced from adjacent second pillars by a portion of the first pillar.

18. The semiconductor device of claim 17, further comprising a fourth semiconductor material of the second conductivity type extending between adjacent gate electrodes in the first region and in electrical contact with the first semiconductor material and the second semiconductor material.

19. The semiconductor device of claim 18, further comprising a first electrode in electrical contact with the fourth semiconductor material in the first region and a second electrode in electrical contact with the first semiconductor material, the second semiconductor material and with the third semiconductor material in the second region.

20. The semiconductor device of claim 15, wherein the first semiconductor material is an epitaxial silicon layer.
